(19) United States
(12) Patent Application Publication
(10) Pub. No.: US 2006/0154079 A1
(43) Pub. Date: Jul. 13, 2006

(54) Epoxy resin composition and semiconductor device

(76) Inventor: Atsunori Nishikawa, Tokyo (JP)

Correspondence Address: SMITH, GAMBRELL & RUSSELL, LLP, 1850 M STREET, N.W., SUITE 800, WASHINGTON, DC, 20036, US

(21) Appl. No.: 10/545,783

(22) PCT Filed: Feb. 13, 2004
(86) PCT No.: PCT/JP04/01569

§ 371 Date: Aug. 16, 2005

(51) Int. Cl. B32B 27/38; C08L 63/00; H01L 21/56; B32B 37/00

(52) U.S. Cl. 428/413; 523/400; 438/127

(57) ABSTRACT

The object of the present invention is to provide an epoxy resin composition for semiconductor encapsulation which is excellent in flowability, adhesion to substrates, flame retardancy and solder crack resistance without using bromine-containing organic compounds and antimony compounds. According to the present invention, there is provided an epoxy resin composition for semiconductor encapsulation characterized by including, as essential components, a phenolic aralkyl type epoxy resin having a biphenyl structure, a phenolic aralkyl resin having a biphenyl structure, a curing accelerator, an inorganic filler, a specific silane coupling agent having a secondary amine, and a specific silane coupling agent having a mercapto group.

### TECHNICAL FIELD

The present invention relates to an epoxy resin composition for encapsulation of semiconductors, and a semiconductor device obtained using the composition.

### BACKGROUND OF THE INVENTION

As a method for encapsulation of semiconductor elements such as IC and LSI, the transfer molding of an epoxy resin composition has been employed for a long time because it is low in cost and suitable for mass-production. Further, as for the reliability, improvement of characteristics has been attempted by amelioration of epoxy resins or phenolic resins as curing agents. However, high integration of semiconductors has advanced year by year in accordance with the recent market demand for miniaturization, weight-saving and high-performance of electronic equipment. Moreover, the area mounting of semiconductor devices is being facilitated, and, consequently, demand for epoxy resin compositions for semiconductor encapsulation becomes increasingly severer. Therefore, there are problems which cannot be solved by the conventional epoxy resin compositions.

Usually, bromine-containing organic compounds and antimony compounds such as antimony trioxide and antimony tetroxide are added to epoxy resin compositions in order to impart flame retardancy to the compositions, but use of these compounds is undesirable from the environmental and hygienic points. Under the circumstances, it has been proposed to use resins having many aromatic rings in the structure as epoxy resin compositions excellent in flame retardancy without using bromine-containing organic compounds and antimony compounds (see, for example, JP-A-11-140277, particularly, pages 2-11). However, the resins having many aromatic rings have the defect of increase of viscosity.

Furthermore, for mounting a semiconductor device on a printed circuit board, a solder containing lead (tin-lead alloy) has been used, but it is also desirable not to use a solder containing lead (tin-lead alloy) from the environmental and hygienic points. The solder containing lead (tin-lead alloy) has a melting point of 183° C., and the soldering temperature for mounting of semiconductor device is 220-240° C., while a solder containing no lead, such as a tin-silver alloy, has a higher melting point and the soldering temperature is about 260° C. Therefore, the stress applied to the semiconductor device at the step of dip soldering or reflow soldering increases to cause delamination at the interface between the cured epoxy resin composition and each bonded portion subjected to various platings such as gold plating or silver plating in the semiconductor device, particularly, on semiconductor elements, lead frames and inner leads, resulting in conspicuous deterioration in reliability.

In order to solve the problem of deterioration in reliability caused by soldering treatment, there are proposed a method of increasing the amount of an inorganic filler contained in the epoxy resin composition to attain decrease of moisture absorption, increase of strength and decrease of heat expansion, thereby to improve soldering crack resistance, and a method of using a resin of low melt viscosity, thereby to maintain low viscosity and high flowability during molding (see, for example, JP-A-64-65116, particularly, pages 2-7). The solder crack resistance can be considerably improved by employing the above method, but there is a problem that with increase of the filling ratio of the inorganic filler, the flowability is sacrificed and vacant voids are apt to be produced in the package. Thus, it is further proposed to add various coupling agents such as aminosilane to allow both the flowability and the solder crack resistance to coexist together (see, for example, JP-A-2-218735, particularly, pages 1-9). However, delamination at the interface of cured epoxy resin composition and each bonded portion subjected to various platings such as gold plating or silver plating cannot be prevented, and an epoxy resin composition for semiconductor encapsulation which has a sufficiently satisfactory solder crack resistance cannot still be obtained.

### DISCLOSURE OF THE INVENTION

The object of the present invention is to provide an epoxy resin composition for semiconductor encapsulation which is excellent in flowability and solder crack resistance, and a semiconductor device obtained using the composition.

That is, the present invention provides [1] an epoxy resin composition for semiconductor encapsulation which comprises, as essential components, (A) an epoxy resin represented by the following formula (1), (B) a phenolic resin represented by the following formula (2), (C) a curing accelerator, (D) an inorganic filler, (E) a silane coupling agent represented by the following formula (3), and (F) a silane coupling agent represented by the following formula (4): 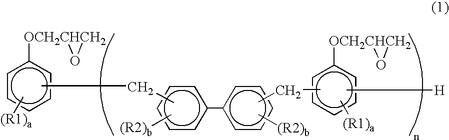
where R1 and R2 each represents a hydrogen atom or an alkyl group of 1-4 carbon atoms and may be the same or different, a is an integer of 0-3, b is an integer of 0-4, and n which is an average value is a positive number of 1-5; 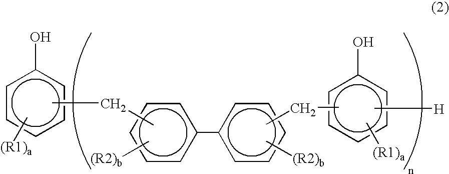
where R1 and R2 each represents a hydrogen atom or an alkyl group of 1-4 carbon atoms and may be the same or different, a is an integer of 0-3, b is an integer of 0-4, and n which is an average value is a positive number of 1-5;
R¹—NH—R²—Si(OR³)ₙR⁴₃₋ₙ (3)
where R¹ represents an organic group of 1-12 carbon atoms, R², R³ and R⁴ each represents a hydrocarbon group of 1-12 carbon atoms, and n is an integer of 1-3; and
HS—R⁵—Si(OR⁶)ₙR⁷₃₋ₙ (4)
where R⁵ represents an organic group of 1-12 carbon atoms, R⁶ and R⁷ each represents a hydrocarbon group of 1-12 carbon atoms, and n is an integer of 1-3.

The present invention further provides [2] a semiconductor device obtained by encapsulating a semiconductor element using the epoxy resin composition for semiconductor encapsulation of the above [1].

### MODE FOR CARRYING OUT THE INVENTION

The epoxy resin used in the present invention which is represented by the formula (1) has a hydrophobic and rigid biphenylene structure between epoxy groups, and a cured product of an epoxy resin composition comprising the epoxy resin is low in moisture absorption and low in elastic modulus in the high temperature area exceeding the glass transition temperature (hereinafter referred to as “Tg”), and excellent in adhesion to semiconductor elements, organic substrates and metal substrates. It further possesses a feature of being high in heat resistance for its low crosslinking density.

The numeral n in the formula (1) is an average value and is a positive number of 1-5, preferably 1-3. If n is smaller than the lower limit, the curability of the epoxy resin composition may be deteriorated. If n exceeds the upper limit, viscosity of the epoxy resin increases and the flowability of the epoxy resin composition may decrease. The epoxy resins represented by the formula (1) may be used each alone or in combination of two or more.

Of the epoxy resins represented by the formula (1), especially preferred is the epoxy resin represented by the following formula (5).

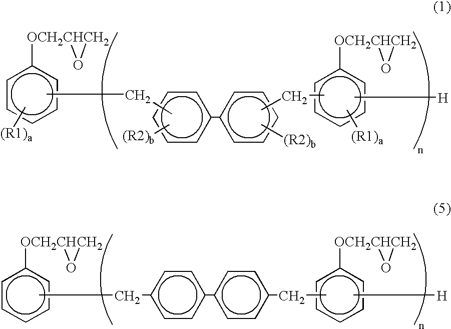

Other epoxy resins may be used together so far as the inherent properties of the epoxy resins represented by the formula (1) are not damaged. In case other epoxy resins are used together, it is desirable to use generally the monomers, oligomers or polymers which have epoxy groups in the molecule and have a viscosity of as low as possible. As the other epoxy resins, mention may be made of, for example, phenolic novolak type epoxy resins, cresol novolak type epoxy resins, biphenyl type epoxy resins, bisphenol type epoxy resins, stilbene type epoxy resins, triphenolmethane type epoxy resins, phenolic aralkyl type epoxy resins (having a phenylene structure), naphthol type epoxy resins, naphthalene type epoxy resins, alkyl-modified triphenolmethane type epoxy resins, triazine ring-containing epoxy resins, dicyclopentadiene-modified phenolic type epoxy resins, etc. These may be used each alone or in a combination of two or more.

The amount of the epoxy resin represented by the formula (1) is preferably not less than 30% by weight, especially preferably not less than 50% by weight based on the total weight of the epoxy resins. If the amount is less than the lower limit, the flame retardancy tends to be insufficient.

The phenolic resin used in the present invention which is represented by the formula (2) has a hydrophobic and rigid biphenylene structure between phenolic hydroxyl groups, and a cured product of an epoxy resin composition containing the phenolic resin is low in moisture absorption and low in elastic modulus in the high temperature area exceeding Tg, and excellent in adhesion to semiconductor elements, organic substrates and metal substrates. It further possesses a feature of being high in heat resistance for its low crosslinking density.

The numeral n in the formula (2) is an average value and is a positive number of 1-5, preferably 1-3. If n is smaller than the lower limit, the curability of the epoxy resin composition may deteriorate. If n exceeds the upper limit, viscosity increases and the flowability of the epoxy resin composition may decrease. The phenolic resins represented by the formula (2) may be used each alone or in a combination of two or more.

Of the phenolic resins represented by the formula (2), especially preferred is the phenolic resin represented by the following formula (6).

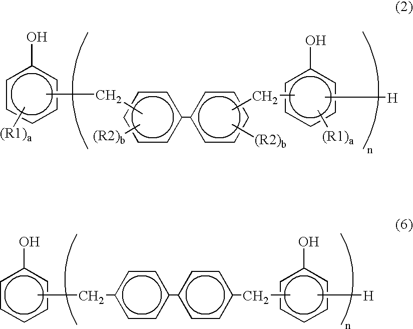

Other phenolic resins may be used together with the phenolic resins represented by the formula (2) so far as the inherent properties of the phenolic resins represented by the formula (2) are not damaged. In case other phenolic resins are used, it is desirable to use generally the monomers, oligomers or polymers which have phenolic hydroxyl groups in the molecule and have a viscosity of as low as possible. As the other phenolic resins, mention may be made of, for example, phenolic novolak resins, cresol novolak resins, phenolic aralkyl resins (having a phenylene structure), naphthol aralkyl resins, triphenolmethane resins, terpene-modified phenolic resins, dicyclopentadiene-modified phenolic resins, etc. These may be used each alone or in combination of two or more.

The amount of the phenolic resin represented by the formula (2) is preferably not less than 30% by weight, especially preferably not less than 50% by weight based on the total weight of the phenolic resins. If the amount is less than the lower limit, the flame retardancy tends to be insufficient.

The equivalent ratio of the epoxy groups in the whole epoxy resins and the phenolic hydroxyl groups in the whole phenolic resins is preferably 0.5-2, more preferably 0.7-1.5. If the ratio is outside the above range, moisture resistance, curability, etc. may be deteriorated.

The inorganic fillers used in the present invention are not particularly limited, and examples thereof are fused crush silica, fused spherical silica, crystalline silica, secondary agglomerated silica, alumina, titanium white, aluminum hydroxide, magnesium hydroxide, zinc borate, zinc molybdate, etc., and fused spherical silica is especially preferred. As for the shape of the fused spherical silica, it is preferred that the shape is infinitely close to true sphere for attaining superior flowability and that the particle size distribution is broad.

The content of all the inorganic matters including the inorganic filler and optionally added metal hydroxides, inorganic ion exchangers, etc. is not particularly limited, but is preferably not less than 84% by weight and not more than 94% by weight in the whole epoxy resin composition. If the content is lower than the lower limit, low moisture absorption of the cured product of the epoxy resin composition cannot be attained, which may result in insufficient solder crack resistance. If it exceeds the upper limit, there may occur troubles such as short molding due to decrease in flowability of the epoxy resin composition or distortion of gold wires in the semiconductor device due to increase of viscosity.

The present invention gives flame retardancy to the epoxy resin composition without using bromine-containing organic compounds and antimony compounds. The contents of bromine atom and antimony atom are not more than 0.05% by weight in the whole epoxy resin composition, respectively. This means that for economical reasons, bromine atom and antimony atom are not added except for the trace amounts of the components contained in the starting materials or incorporated during preparation of the epoxy resin composition.

The inorganic filler used in the present invention is preferably previously mixed well. Furthermore, if necessary, the inorganic filler may be previously coated with a coupling agent, an epoxy resin or a phenolic resin. The coating can be carried out by a method of mixing them using a solvent and then removing the solvent, a method of directly adding the coupling agent, the epoxy resin or the phenolic resin to the inorganic filler and mixing them by a mixer, and other methods.

The curing accelerators used in the present invention are not particularly limited so long as they accelerate the reaction of epoxy group and phenolic hydroxyl group. Examples of the accelerators are diazabicycloalkenes such as 1,8-diazabicyclo(5,4,0)undecene-7 and derivatives thereof, amine compounds such as tributylamine and benzyldimethylamine, imidazole compounds such as 2-methylimidazole, organic phosphines such as triphenylphosphine and methyldiphenylphosphine, and tetra-substituted phosphonium.tetra-substituted borates such as tetraphenylphosphonium.tetraphenyl borate, tetraphenylphosphonium.tetrabenzoic acid borate, tetraphenylphosphonium.tetranaphthoic acid borate, tetraphenylphosphonium.tetranaphthoyloxy borate, and tetraphenylphosphonium.tetranaphthyloxy borate. These may be used each alone or in combination of two or more.

The silane coupling agents represented by the formula (3) in the present invention are essential. The silane coupling agents represented by the formula (3) may be used each alone or in combination of two or more. The amount of the silane coupling agents added is not particularly limited, but is preferably 0.01-3% by weight, more preferably 0.05-1% by weight in the whole epoxy resin composition. If the amount is less than the lower limit, sufficient flowability may not be obtained, and if it exceeds the upper limit, the curability is apt to be deteriorated.
R¹—NH—R²—Si(OR³)ₙR⁴₃₋ₙ (3)

The silane coupling agents represented by the formula (4) in the present invention are essential. The silane coupling agents represented by the formula (4) may be used each alone or in combination of two or more. The amount of the silane coupling agents added is not particularly limited, but is preferably 0.01-3% by weight, more preferably 0.05-1% by weight in the whole epoxy resin composition. If the amount is less than the lower limit, sufficient adhesion may not be obtained, and if it exceeds the upper limit, the curability is apt to be deteriorated.
HS—R⁵—Si(OR⁶)ₙR⁷₃₋ₙ (4)

It is essential in the present invention to use the silane coupling agent represented by the formula (3) and the silane coupling agent represented by the formula (4) in combination. When only one of them is added, flowability and solder crack resistance are insufficient.

If necessary, to the epoxy resin composition of the present invention there may be optionally added coupling agents, for example, silane coupling agents other than those represented by the formula (3), such as aminosilanes and silane coupling agents other than those represented by the formula (4), such as mercaptosilanes, epoxysilanes, alkylsilanes, ureidosilanes, and vinylsilanes, titanate coupling agents, aluminum coupling agents, aluminum/zirconium coupling agents, coloring agents such as carbon black, releasing agents such as natural waxes and synthetic waxes, low-stress additives such as rubbers, and other agents.

The epoxy resin composition of the present invention can be obtained by sufficiently uniformly mixing the starting materials using a mixer or the like, then melt kneading the mixture by a hot roll, a kneader or the like, cooling the kneaded mixture and then grinding the mixture.

In order to produce semiconductor devices by encapsulating various electronic parts such as semiconductor elements using the epoxy resin composition of the present invention, known molding methods such as, for example, transfer molding, compression molding and injection molding can be employed to effect curing and molding.

The present invention will be explained by the following examples, which should not be construed as limiting the invention in any manner. The mixing ratio is part by weight.

Coupling agents and compounds used in the examples and comparative examples will be shown below.

Coupling agent 1: A coupling agent represented by the following formula (7) (KBM-573 manufactured by Shin-Etsu Chemical Co., Ltd.)

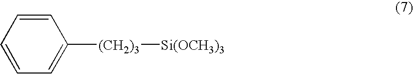

Coupling agent 2: A coupling agent represented by the following formula (8) (X12-806 manufactured by Shin-Etsu Chemical Co., Ltd.)
CH₃(CH₂)₃—NH—(CH₂)₃—Si(OCH₃)₃ (8)

Coupling agent 3: A coupling agent represented by the following formula (9) (KBM-803 manufactured by Shin-Etsu Chemical Co., Ltd.)
HS—(CH₂)₃—Si(OCH₃)₃ (9)

Coupling agent 4: A coupling agent represented by the following formula (10) (KBM-403 manufactured by Shin-Etsu Chemical Co., Ltd.)

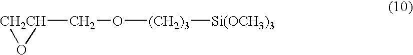

### EXAMPLE 1

Epoxy resin 1: An epoxy resin represented by the following formula (5) (NC3000P manufactured by Nippon Kayaku Co., Ltd. and having a softening point of 58° C. and an epoxy equivalent of 273, which is hereinafter referred to as “E-1”)
- - - 49 parts by weight

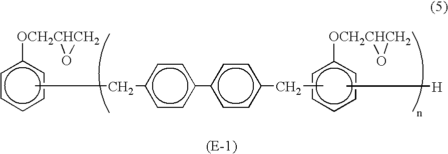

Phenolic resin 1: A phenolic resin represented by the following formula (6) (MEH-7851SS manufactured by Meiwa Kasei Co., Ltd. and having a softening point of 107° C. and a hydroxyl equivalent of 204, which is hereinafter referred to as “H-1”)
- - - 42 parts by weight

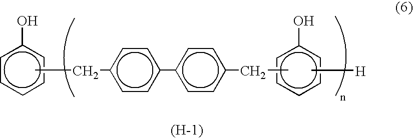

1,8-Diazabicyclo(5,4,0)undecene-7 (hereinafter referred to as “DBU”)

- - - 5 parts by weight

| | |
|---|---|
| Fused spherical silica (average particle | 870 parts by weight |
| diameter 21 μm) | |
| Coupling agent 1 | 3 parts by weight |
| Coupling agent 2 | 3 parts by weight |
| Carbon black | 3 parts by weight |
| Carnauba wax | 5 parts by weight |

The above components were mixed by a mixer, and the mixture was kneaded at 95° C. for 8 minutes using a hot roll, cooled and then ground to obtain an epoxy resin composition. The resulting epoxy resin composition was evaluated by the following methods. The results are shown in Table 1.

Evaluation Methods

Spiral flow (cm): This was measured using a mold for spiral flow measurement (which was in accordance with EMMI-1-66) at a mold temperature of 175° C. under a pressure of 6.9 MPa for a curing time of 120 seconds.

Adhesion (N/mm²): A specimen for adhesion strength test was formed on a lead frame of 2 mm×2 mm×2 mm using a transfer molding machine under the conditions of a mold temperature of 175° C., under a pressure of 9.8 MPa and a curing time of 120 seconds. As the lead frame, two kinds of lead frames of a copper frame plated with silver (frame 1) and a NiPd alloy frame plated with gold (frame 2) were used. Thereafter, a shear strength of the cured product of the epoxy resin composition and the frame was measured using an automatic shear strength measuring apparatus (PC2400 manufactured by DAGE Co., Ltd.).

Solder crack resistance: A 80 pQFP (a NiPd alloy frame plated with gold, the chip size: 6.0 mm×6.0 mm) was molded using a low-pressure transfer molding machine at a molding temperature of 175° C., under a pressure of 8.3 MPa for a curing time of 120 seconds, after-baked by a heat treatment at 175° C. for 8 hours, then subjected to a moistening treatment at 85° C. and a relative humidity of 85% for 120 hours, and then subjected to an IR reflow treatment at 260° C. Occurrence of delamination and cracking inside the package was examined by a supersonic flaw detector. The soldering crack resistance is shown by the number of defective packages among ten packages.

Flame retardancy: A molded product of 127 mm in length, 12.7 mm in width and 1.6 mm in thickness was produced using a transfer molding machine at a mold temperature of 175° C. under a pressure of 9.8 MPa for a curing time of 120 seconds, post-cured by a heat treatment at 175° C. for 8 hours, and then the resulting molded product was subjected to a moistening treatment in an atmosphere of 23° C. and a relative humidity of 50% for 48 hours and subjected to a flame retardancy test in accordance with UL-94.

### EXAMPLES 2-5 AND COMPARATIVE EXAMPLES 1-5

Epoxy resin compositions were prepared in the same manner as in Example 1 in accordance with the formulations shown in Table 1, and were evaluated in the same manner as in Example 1. The results are shown in Table 1.

Starting materials other than those used in Example 1 are shown below.

Epoxy resin 2: An epoxy resin mainly composed of the epoxy resin represented by the following formula (11) (YX-4000 manufactured by Japan Epoxy Resin Co., Ltd. and having an epoxy equivalent of 190 g/eq and a melting point of 105° C., which is hereinafter referred to as “E-2”).

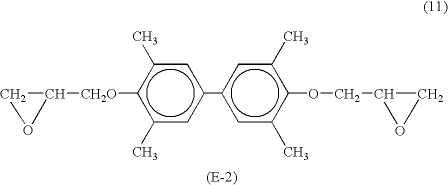

Phenolic resin 2: A phenolic resin represented by the following formula (12) (XLC-LL manufactured by Mitsui Chemical Co., Ltd. and having a hydroxyl group equivalent of 165 g/eq and a softening point of 79° C., which is hereinafter referred to as “H-2”).

TABLE 1

| | | | | | | | | | | (12) |
|---|---|---|---|---|---|---|---|---|---|---|
| 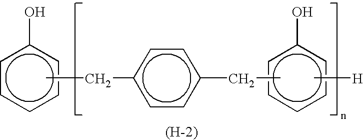 | | | | | | | | | | |
| | Example | | | | | Comparative Example | | | | |
| | 1 | 2 | 3 | 4 | 5 | 1 | 2 | 3 | 4 | 5 |
| E-1 | 66 | 76 | 49 | 61 | 65 | 66 | 66 | 66 | | |
| E-2 | | | | | | | | | 51 | 51 |
| H-1 | 48 | 54 | 36 | 43 | 46 | 49 | 49 | 48 | | |
| H-2 | | | | | | | | | 43 | 43 |
| DBU | 5 | 5 | 5 | 5 | 5 | 5 | 5 | 5 | 5 | 5 |
| Fused spherical silica | 870 | 850 | 890 | 870 | 870 | 870 | 870 | 870 | 890 | 890 |
| Coupling agent 1 | 2 | | 2 | 12 | 0.5 | 2 | | | 2 | |
| Coupling agent 2 | | 5 | | | | | | | | |
| Coupling agent 3 | 1 | 2 | 10 | 0.5 | 5 | | 2 | 1 | 1 | 1 |
| Coupling agent 4 | | | | | | | | 2 | | 2 |
| Carbon black | 3 | 3 | 3 | 3 | 3 | 3 | 3 | 3 | 3 | 3 |
| Carnauba wax | 5 | 5 | 5 | 5 | 5 | 5 | 5 | 5 | 5 | 5 |
| Spiral flow (cm) | 114 | 133 | 100 | 122 | 102 | 101 | 88 | 88 | 98 | 92 |
| Frame 1 Adhesion (N/mm²) | 3.7 | 3.9 | 3.7 | 3.4 | 3.5 | 2.6 | 3.0 | 2.7 | 2.7 | 2.5 |
| Frame 2 Adhesion (N/mm²) | 3.4 | 3.4 | 3.5 | 3.1 | 3.1 | 2.3 | 2.6 | 2.4 | 2.5 | 2.2 |
| Solder crack resistance | 0 | 0 | 0 | 0 | 0 | 5 | 6 | 5 | 2 | 4 |
| (the number of defective | | | | | | | | | | |
| packages in 10 packages) | | | | | | | | | | |
| Flame retardancy | V-0 | V-0 | V-0 | V-0 | V-0 | V-0 | V-0 | V-0 | V-1 | V-1 |

Comparison of Example 1 with Comparative Examples 1 and 2 shows that both the flowability and the adhesion were improved by using coupling agents 1 and 2 in combination, not using them each alone. The effect was not exhibited when coupling agents 3 and 4 were used in combination as in Comparative Example 3, and, furthermore, was also not exhibited when other resins were used as in Comparative Example 4. Thus, the effect is peculiar to the present invention.

### INDUSTRIAL APPLICABILITY

According to the present invention, an epoxy resin composition is obtained which can provide a satisfactory flame retardancy without using bromine-containing organic compounds and antimony compounds and furthermore which has good flowability and adhesion to a substrate. The semiconductor device prepared using the epoxy resin composition is superior in solder crack resistance.

1. An epoxy resin composition for semiconductor encapsulation which comprises, as essential components, (A) an epoxy resin represented by the formula (1), (B) a phenolic resin represented by the formula (2), (C) a curing accelerator, (D) an inorganic filler, (E) a silane coupling agent represented by the formula (3), and (F) a silane coupling agent represented by the formula (4): 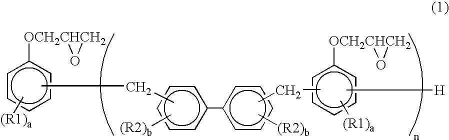
where R1 and R² each represents a hydrogen atom or an alkyl group of 1-4 carbon atoms and may be the same or different, a is an integer of 0-3, b is an integer of 0-4, and n which is an average value is a positive number of 1-5; 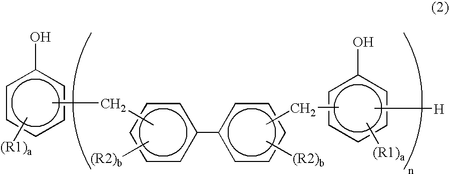
where R1 and R² each represents a hydrogen atom or an alkyl group of 1-4 carbon atoms and may be the same or different, a is an integer of 0-3, b is an integer of 0-4, and n which is an average value is a positive 1-5;
R¹—NH—R²—Si(OR³)ₙR⁴₃₋ₙ (3)
where R¹ represents an organic group of 1-12 carbon atoms, R², R³ and R⁴ each represents a hydrocarbon group of 1-12 carbon atoms, and n is an integer of 1-3;
HS—R⁵—Si(OR⁶)ₙR⁷₃₃₋ₙ (4)
where R⁵ represents an organic group of 1-12 carbon atoms, R⁶ and R⁷ each represents a hydrocarbon group of 1-12 carbon atoms, and n is an integer of 1-3.

2. A semiconductor device obtained by encapsulating a semiconductor element using the epoxy resin composition for semiconductor encapsulation according to claim 1.
